(19) United States
(12) Patent Application Publication
(10) Pub. No.: US 2012/0175700 A1
(43) Pub. Date: Jul. 12, 2012

(54) TRENCH MOS RECTIFIER

(75) Inventor: Fu-Yuan HSIEH, Banciao City (TW)

(73) Assignee: FORCE MOS TECHNOLOGY CO., LTD., Banciao City (TW)

(21) Appl. No.: 12/985,361

(22) Filed: Jan. 6, 2011

(51) Int. Cl. H01L 29/78

(52) U.S. Cl. 257/334; 257/E29.262

(57) ABSTRACT

A semiconductor device comprising trench MOSFET as MOS rectifier is disclosed. For ESD capability enhancement and reverse recovery charge reduction, a built-in resistor in the semiconductor device is introduced according to the present invention between gate and source. The built-in resistor is formed by a doped poly-silicon layer filled into multiple trenches.

### FIELD OF THE INVENTION

This invention relates generally to the device configuration for fabricating the semiconductor power device. More particularly, this invention relates to an improved and novel device configuration for providing a MOS (Metal Oxide Semiconductor) rectifier with enhanced ESD (Electro-Static discharge) capability and reduced reverse recovery charge.

### BACKGROUND OF THE INVENTION

FIG. 1A shows a circuit diagram of a trench MOS rectifier 100 with a parasitic diode 101 as shunting device named as “pseudo-Schottky” diode in U.S. Pat. No. 5,818,084 which comprising: a gate electrode 105, a source electrode 106, a body 107 and a drain electrode 108. To form the “pseudo-Schottky” diode configuration of majority carrier device, the gate electrode 105, the source electrode 106 and the body 107 are all connected to a positive voltage, while only the drain electrode 108 is connected to a negative voltage. The MOS portion of the trench MOS rectifier 100 will begin to conduct due to body effect at a threshold voltage (Vth) ranging from 0.3˜0.5V, which is significantly less than the conventional parasitic diode (0.6˜0.8V), thus resulting in a faster recovery time and a lower peak reverse current.

However, there are still some disadvantages constraining the performance of the trench MOS rectifier 100. Refer to FIG. 1B for cross-sectional view of the trench MOS rectifier 100 shown in FIG. 1A. As mentioned above, for using the N-channel trench MOS rectifier 100 for “pseudo-Schottky” function, the gate electrode 105 in trench 111 is required to be shorted with a n+ source region 106, while Vth must be kept as lower as possible so that channel region can be turned on due to the body effect when a small positive bias is applied to the n+ source region 106. Therefore, in order to make a low Vth without punch-through between anode region (labeled as A) and cathode region (labeled as C) of the parasitic diode, a thin gate oxide 109 is normally used to separate the gate electrode 105 from the n+ source region 106, the P body 107 and N epitaxial layer 110, which will lead to a poor ESD capability due to the thin gate oxide 109 degrades the breakdown voltage supported by the trench MOS rectifier 100. Moreover, for high current application such as DC/DC converter, the parasitic bipolar will be triggered on, resulting in low converter efficiency due to increased reverse recovery charge in the parasitic bipolar.

Furthermore, a high Rds (resistance between the drain and source) inherently exists in the prior art because that the use of planar source-body contact limits device shrinkage for Rds reduction. Besides, a JFET (Junction field Effect Transistor) is formed between two deep P body regions 107 as result of the P body deeper than trench depth, which also causes high Rds.

Accordingly, it would be desirable to provide a new and improved MOS rectifier with its parasitic diode as shunting device, which has the properties of better ESD capability, lower reverse recovery charge and lower Rds.

### SUMMARY OF THE INVENTION

It is therefore an aspect of the present invention to provide a new and improved trench MOS rectifier with parasitic PN diode by disposing a built-in gate resistor Rg between a gate electrode and a source electrode (or anode electrode of the trench MOS rectifier) of the trench MOS rectifier for ESD capability enhancement and reverse recovery charge reduction. When the source electrode is biased at a positive voltage while the drain electrode is connected to a negative voltage, the inventive Rg helps to prevent a high voltage transient signal of static discharge from imposing on the gate electrode. Besides, the gate resistor Rg reduces the reverse recovery charge as result of increasing drain voltage by passing displacement current through the built-in gate resistor and parasitic capacitor between the gate electrode and the drain electrode. Therefore, the present invention can be implemented by formed in a semiconductor chip comprising: the source electrode, the gate electrode and the drain electrode; the gate electrode connected to the source electrode through an embedded gate resistor with a resistance from 0.5 ohms to 200 ohms built in the semiconductor device; and the source electrode and the drain electrode served as an anode electrode and a cathode electrode for a MOS rectifier, respectively. In a preferred embodiment, the semiconductor device can be implemented by comprising: a substrate of a first conductivity type and an epitaxial layer of said first conductivity type, wherein said epitaxial layer formed onto top surface of said substrate and having lower doping concentration than said substrate; a body region of a second conductivity type opposite to said first conductivity type, wherein said body region located near top surface of said epitaxial layer; a plurality of first type trenched gates and at least a second type trenched gates penetrating through said body region and extending into said epitaxial layer, said first type trenched gates as gate electrode disposed in an active area and extended to a gate contact area in which said second type trenched gate having a greater width than said first type trench gates in said active area as wider trenched gates for electrically connecting to an source metal as said source electrode; a source region of said first conductivity type disposed only in said active area but not in termination area and the regions adjacent to said second type trenched gate in said gate contact area; said source and body regions shorted with said source metal, and connected to said first type trenched gates through said embedded gate resistor disposed between said first type trenched gates and second type trenched gate; and a drain metal formed on rear side of said substrate as said drain electrode.

In accordance with another aspect of the present invention, the body region is shallower than the first and second type trenched gates to eliminate the JFET resistance introduced in the prior art and for Rds reduction.

In accordance with another aspect of the present invention, trenched source-body contact is employed in some preferred embodiments for device cell shrinkage and for further Rds reduction.

The trench MOS rectifier of the present invention further comprises one or more detail features as below: the embedded gate resistor is a doped poly-silicon layer filled in multiple trenches in the epitaxial layer as an overall gate distributive resistance; the source metal is connected to the source region, the body region and the second type trenched gate by planar contact; the semiconductor device further comprising an ohmic body contact region of the second conductivity type within the body region and between a pair of the source regions, wherein the ohmic body contact region has a higher doping concentration than the body region to reduce contact resistance; the source metal is formed onto a contact interlayer and connected to the source region and the body region by trenched source-body contact positioned in a source-body contact trench which being penetrating through the contact interlayer, the source region and extending into the body region; the semiconductor device further comprising an ohmic body contact region of the second conductivity type within the body region and surrounding at least bottom of the source-body contact trench underneath the source region, wherein the ohmic body contact region has a higher doping concentration than the body region to reduce contact resistance; the source metal is formed onto a contact interlayer and connected to the second type trenched gate by a trenched gate contact positioned in a gate contact trench which being penetrating through the contact interlayer and extending into the second type trenched gate; the trenched source-body contact and the trenched gate contact is implemented by a metal plug filling into the source-body contact trench and the gate contact trench, respectively, wherein the metal plug is padded by a barrier layer; the metal plug is tungsten plug and the barrier layer is Ti/TiN or Co/TiN or Ta/TiN; the trenched source-body contact and the trenched gate contact is implemented by filling the source metal into the source-body contact trench and the gate contact trench, respectively; the semiconductor device further comprising multiple of third type trenched gates in the termination area, penetrating through the body region and extending into the epitaxial layer with floating voltage to form trenched floating rings; the termination area comprises a field metal plate and the body region of the second conductivity type underneath, wherein the field metal plate is implemented by extending the source metal covering the body region and portion of the epitaxial layer; the termination area further comprises a deep body region of the second conductivity type underneath the source metal and wrapping around the body region in the termination area and the second type trenched gate; the termination area further comprises multiple deep body regions having floating voltage without having the filed metal plate covered above.

The embedded gate resistor is either an overall gate distributive resistance from the first type trenched gates to the second type trenched gates as shown in FIGS. 6B and 7B composed of a doped poly-silicon layer filled in multiple trenches or a combination of the overall gate distributive resistance and a trenched poly-silicon resistor disposed between the source metal and a gate metal contacting said second type trenched gates through gate contacts as shown in FIG. 9.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is a circuit diagram showing way of connecting a MOSFET as a pseudo-Schottky diode in prior art.

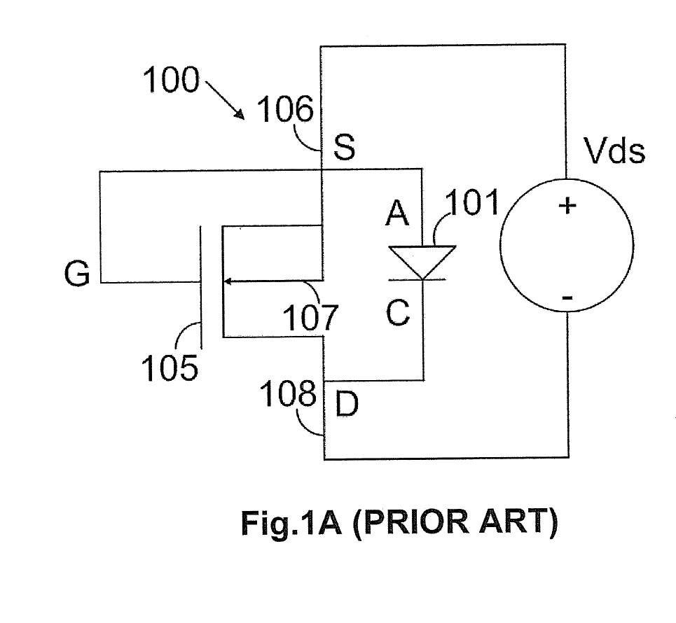

FIG. 1B is a cross-sectional view of the pseudo-Schottky diode in FIG. 1A formed in trenched gate configuration.

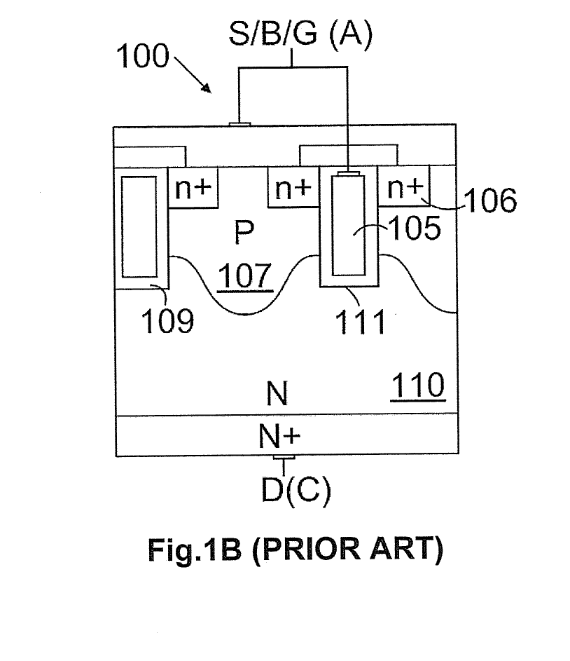

FIG. 2 is a circuit diagram showing there is a built-in embedded gate resistor between the gate and the source of the trench MOS rectifier according to the present invention.

FIG. 3 is a cross-sectional view of a preferred trench MOS rectifier in integrated form according to the present invention.

FIG. 4 is a cross-sectional view of another preferred trench MOS rectifier in integrated form according to the present invention.

FIG. 5 is a cross-sectional view of another preferred trench MOS rectifier in integrated form according the present invention.

FIG. 6A is a cross-sectional view of another preferred trench MOS rectifier in integrated form including termination area according to the present invention.

FIG. 6B is a top view of the trench MOS rectifier in FIG. 6A.

FIG. 7A is a cross-sectional view of another preferred trench MOS rectifier in integrated form including termination area according to the present invention.

FIG. 7B is a top view of the trench MOS rectifier in FIG. 7A.

FIG. 7C is a cross-sectional view of another preferred trench MOS rectifier in integrated form including termination area according to the present invention.

FIG. 7D is a cross-sectional view of another preferred trench MOS rectifier in integrated form including termination area according to the present invention.

FIG. 8 is a cross-sectional view of another preferred trench MOS rectifier in integrated form according the present invention.

FIG. 9 is a top view of the trench MOS rectifier having combination of a trenched poly-silicon resistance and an overall gate distributive resistance.

### DETAILED DESCRIPTION OF THE EMBODIMENTS

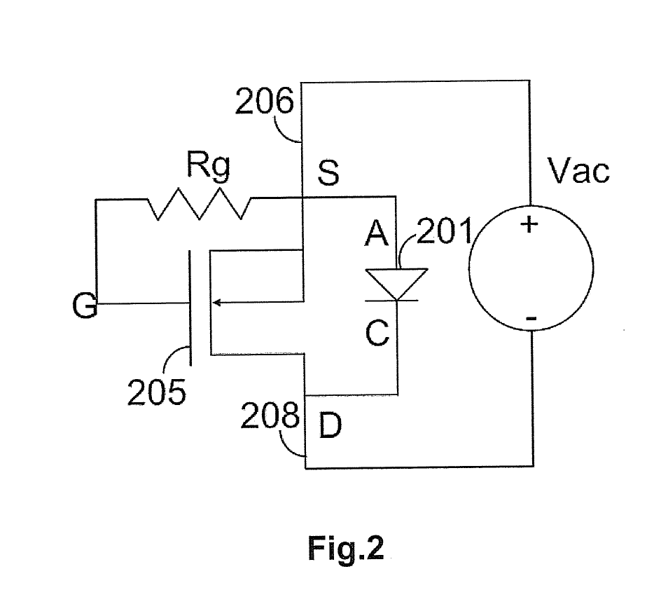

Please refer to FIG. 2 for a circuit diagram of the trench MOS rectifier according to the present invention in which a embedded gate resistor Rg is built between the gate electrode (labeled as G) 205 and the source electrode (labeled as S) 206 which is also the anode electrode (labeled as A) of the parasitic PN diode 201. When the source 206 is biased at a positive voltage relative to the drain electrode (labeled as D) 208, the conduct current will flow through channel region and the parasitic PN diode 201 rather than directly imposing on the gate 205 due to the existence of the built-in Rg, therefore enhancing the ESD capability since the Rg preventing a high electric field from imposing on a relatively thin gate oxide layer discussed above.

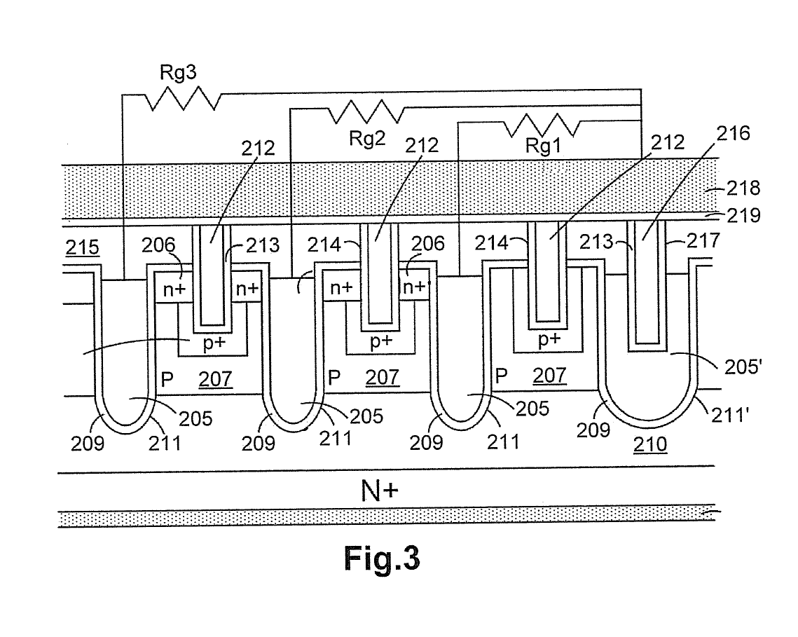

FIG. 3 is a cross-sectional view showing a trench MOS rectifier formed in integrated form according to the present invention which formed in an N epitaxial layer 210 supported on an N+ substrate 200. P body regions 207 are formed in upper portion of the N epitaxial layer 210. A plurality of first type gate trenches 211 and at least one second type gate trench 211′ are formed penetrating through the P body regions 207 and further extending into the N epitaxial layer 210. Adjacent sidewalls of the first type gate trenches 211, n+ source regions 206 are formed encompassed in the P body regions 207. Meanwhile, there is no n+ source regions 206 adjacent sidewall of the second type gate trench 211′. A conductive material is filled into all the gate trenches to serve as a plurality of first type trenched gates and at least a second type trenched gate 205′ having wider width for gate contact. All the first type trenched gates 205 and the second type trenched gate 205′ are separated by an insulating layer 209 which could be a gate oxide layer from the P body regions 207, the n+ source regions 206 and the N epitaxial layer 210. The gate oxide can be a single oxide, or a double gate oxide in the trenched gates including an upper gate portion and a lower gate portion wherein the lower gate portion is surrounded with a lower gate oxide layer having a greater thickness than an upper gate oxide layer surrounding the upper gate portion, and the body region disposed above the lower gate portion of said trenched gate. Between two adjacent of the trenched gates, a trenched source-body contact 212 padded by a barrier layer 213 are formed in a source-body contact trench 214 which being penetrating through a contact interlayer 215, the n+ source regions 206 and extending into the P body regions 207. A trenched gate contact 216 is padded by the barrier layer 213 is formed in a gate contact interlayer 217 which being penetrating through the contact interlayer 215 and extending into the second type trenched gate 205′ for function of gate contact. A source metal layer 218 padded by a resistance-reduction layer 219 is formed onto the contact interlayer 215 to be connected to the n+ source regions 206, the P body regions 207 and the second type trenched gate 205′ via trenched source-body contacts 212 and trenched gate contact 216, respectively. In this preferred embodiment, the trenched source-body contacts 212 and the trenched gate contact 216 is implemented by filling a tungsten plug padded by a barrier layer of Ti/TiN or Co/TiN or Ta/TiN into the source-body contact trenches 214 and the gate contact trench 217, respectively. A p+ ohmic body contact region 221 is formed surrounding at least bottom of each the source-body contact trench 214 adjacent the P body regions 207 to reduce the contact resistance between the trenched source-body contact 212 and the P body regions 207. According to the present invention, in each trench MOS rectifier, an embedded resistor Rg (illustrated as an overall gate distributive resistance which is combination of each gate distributive resistance Rg1, Rg2 and Rg3) is formed connecting the first type trenched gate 205 and the second type trenched gate 205′ which connected to the source metal. On the back surface of the N+ substrate 200, a drain metal 220 is formed functioning as drain electrode for trench MOS rectifier.

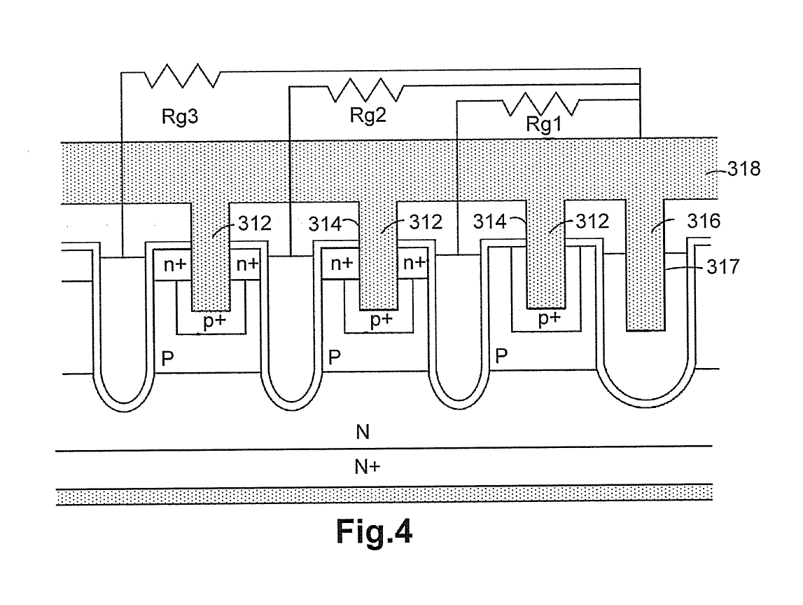

FIG. 4 is a cross-sectional view showing another preferred trench MOS rectifier formed in integrated form according to the present invention which has a similar structure to FIG. 3 except that, in FIG. 4, the trenched source-body contacts 312 and the trenched gate contact 316 are implemented by directly filling the source metal 318 into the source-body contact trenches 314 and the gate contact trench 317, respectively.

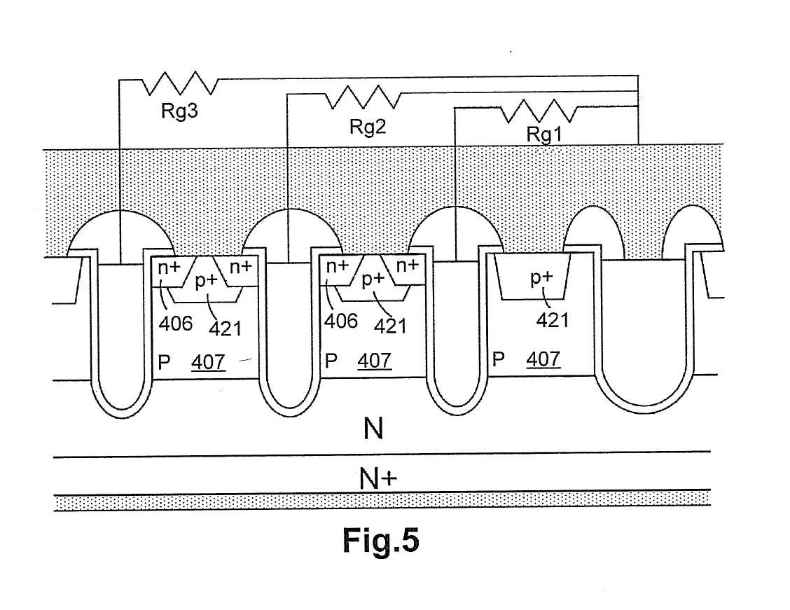

FIG. 5 is a cross-sectional view showing another preferred trench MOS rectifier formed in integrated form according to the present invention which has a similar structure to FIG. 3 except that, in FIG. 5, planar source-body contact and planar gate contact is employed and the p+ ohmic body contact region 421 is formed adjacent the top surface of the P body region 407 between a pair of the n+ source regions 406.

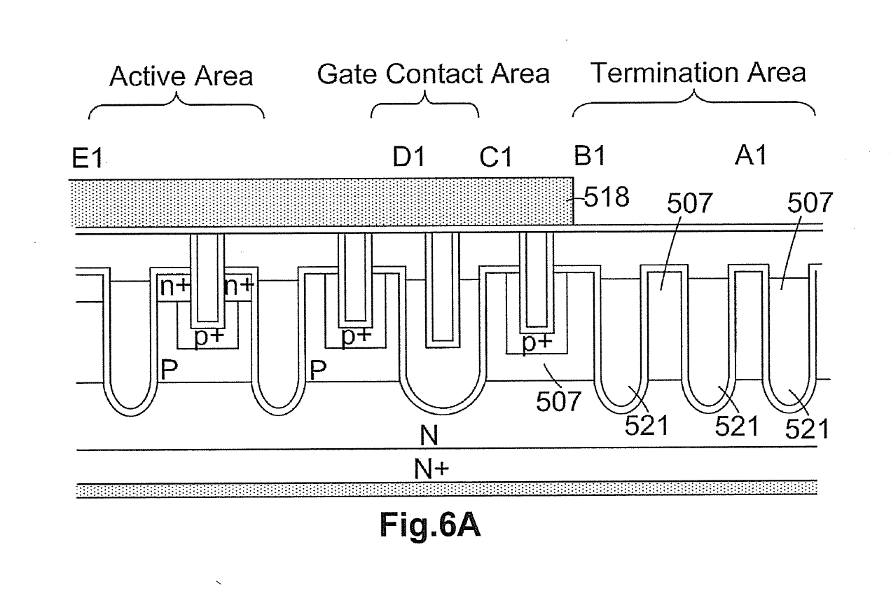

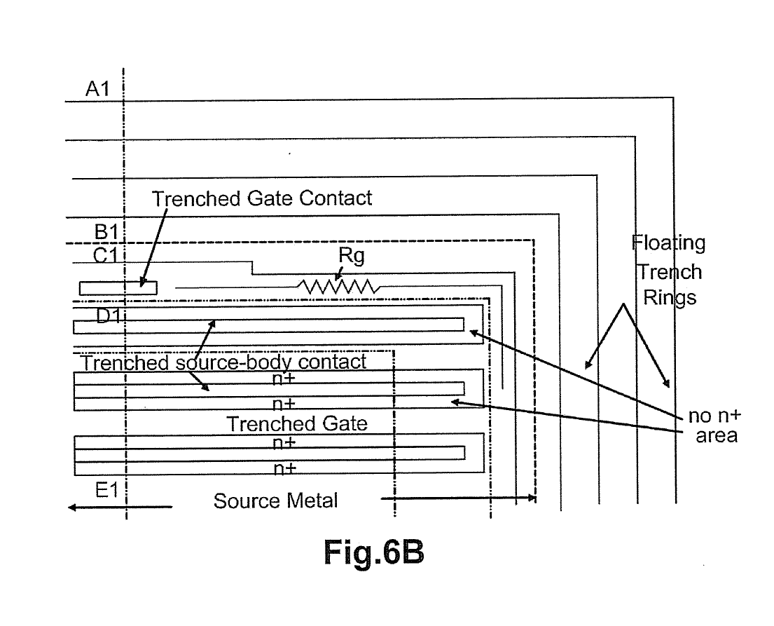

FIG. 6A is a cross-sectional view of another preferred trench MOS rectifier in integrated form including termination area according to the present invention, which is also the E1-D1-C1-B1-A1 cross section of FIG. 6B. In FIG. 6A, the active area and the adjacent gate contact area is similar to FIG. 3, the termination area comprises: a plurality of third type trenched gates 521 having floating voltage to act as floating trench rings; P body regions 507 extending between two adjacent of the third type trenched gates 521 without encompassing n+ source regions. The source metal 518 is only lying over the active area and the gate contact area without lying over the termination area.

FIG. 6B is a top view of FIG. 6A which has stripe cells. From FIG. 6B, it can be seen that, the termination area is surrounding the trench MOS rectifier by trenched floating rings. Multiple Rg are formed between the first type trenched gates and the second type trenched gate which connected to the source metal. The Rg is a doped poly-silicon layer filled in multiples trenches.

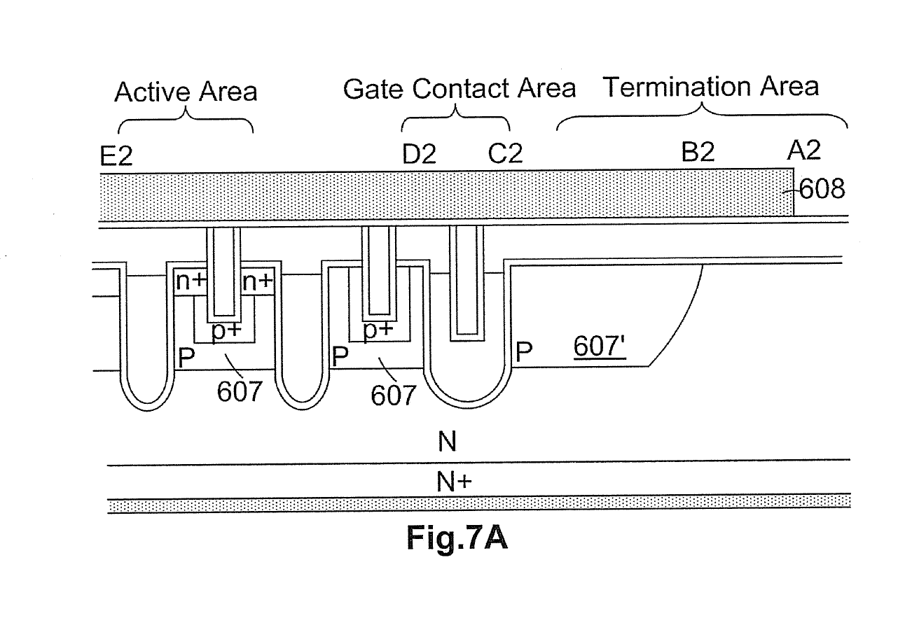

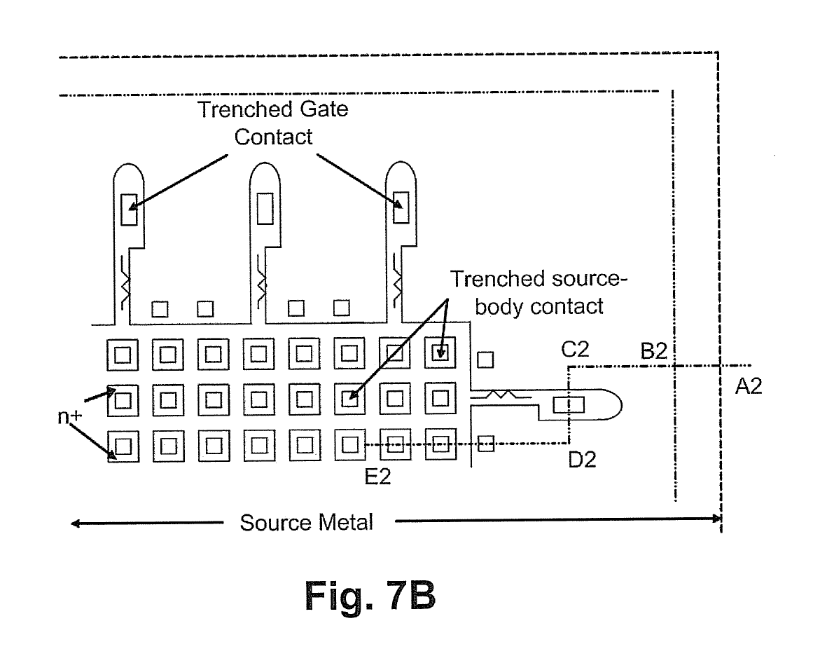

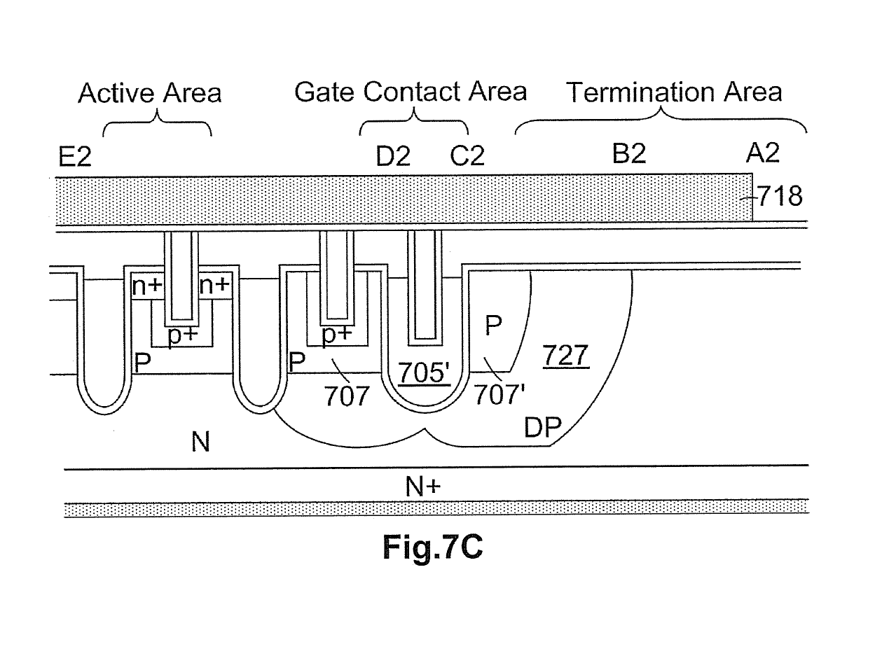

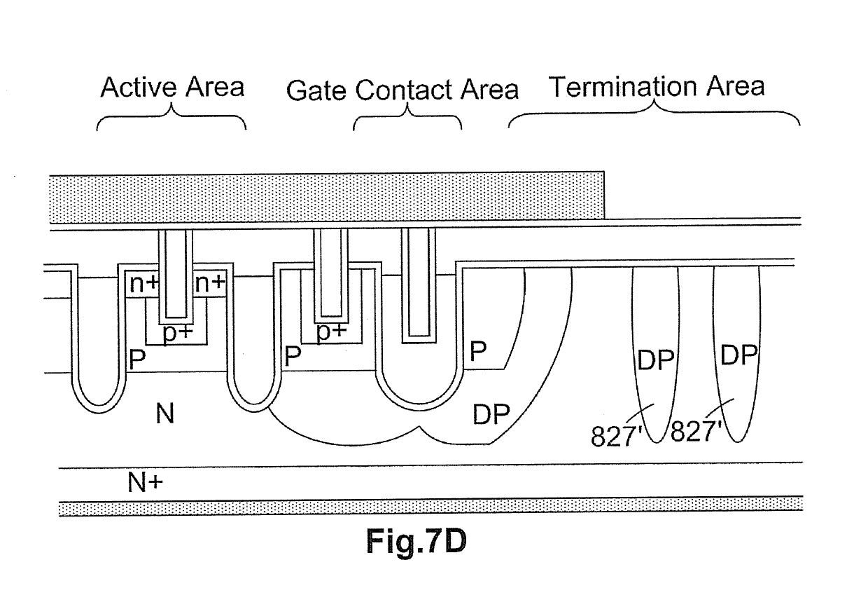

FIG. 7A is a cross-sectional view of another preferred trench MOS rectifier in integrated form including termination area according to the present invention, which is also the E2-D2-C2-B2-A2 cross section of FIG. 7B. In FIG. 7A, the active area and the adjacent gate contact area is similar to FIG. 3, the termination area comprises: a P body region 607′ formed at the same fabricating process as the P body region 607; a filed metal plate implemented by extending the source metal 618 covering the P body region 607′.

FIG. 7B is a top view of FIG. 7A which has closed cells. From FIG. 7B, it can be seen that, the termination area surrounding the trench MOS rectifier is covered by the source metal. Multiple Rg are formed between the first type trenched gates and the second type trenched gate which connected to the source metal. The multiple Rg is a doped poly-silicon layer filled into multiple trenched.

FIG. 7C is a cross-sectional view showing another preferred trench MOS rectifier formed in integrated form according to the present invention which also is the E2-D2-C2-B2-A2 cross section of FIG. 7B. The trench MOS rectifier in FIG. 7C has a similar structure to FIG. 7A except that, in FIG. 7C, there is an additional deep P body 727 surrounding the P body region 707′ underneath the source metal 718 in the termination area and the P body region 707 adjacent the second type trenched gate 705′ to further enhance breakdown voltage.

FIG. 7D is a cross-sectional view showing another preferred trench MOS rectifier formed in integrated form according to the present invention. The trench MOS rectifier in FIG. 7D has a similar structure to FIG. 7C except that, in FIG. 7D, the termination area has additional multiple deep P body regions 827′ having floating voltage without having field metal plate covered above to further enhance breakdown voltage.

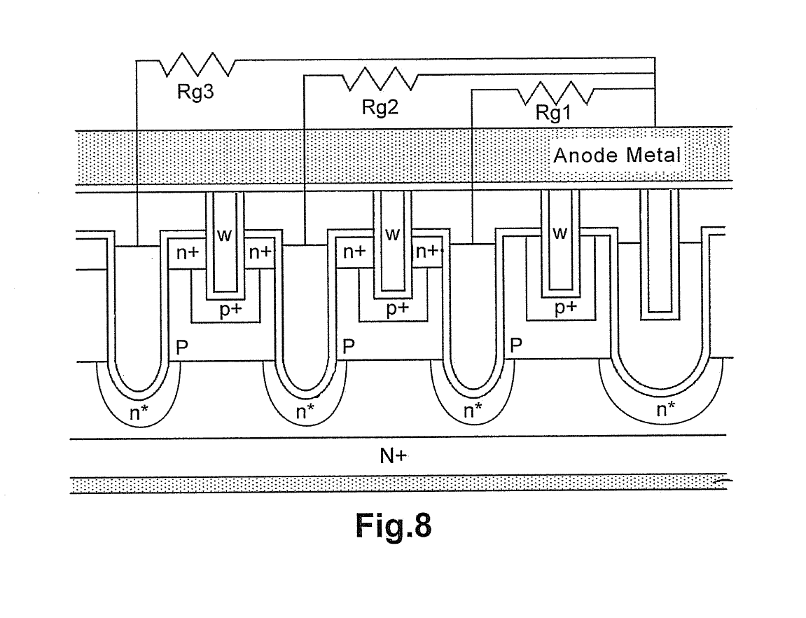

FIG. 8 is a cross-sectional view showing another preferred trench MOS rectifier formed in integrated form according to the present invention which has a similar structure to FIG. 3 except that, in FIG. 8, a on-resistance reduction region n* surrounds at least bottoms of said first and said second type trenched gates and connects to said body region, having doping concentration heavier than said epitaxial layer.

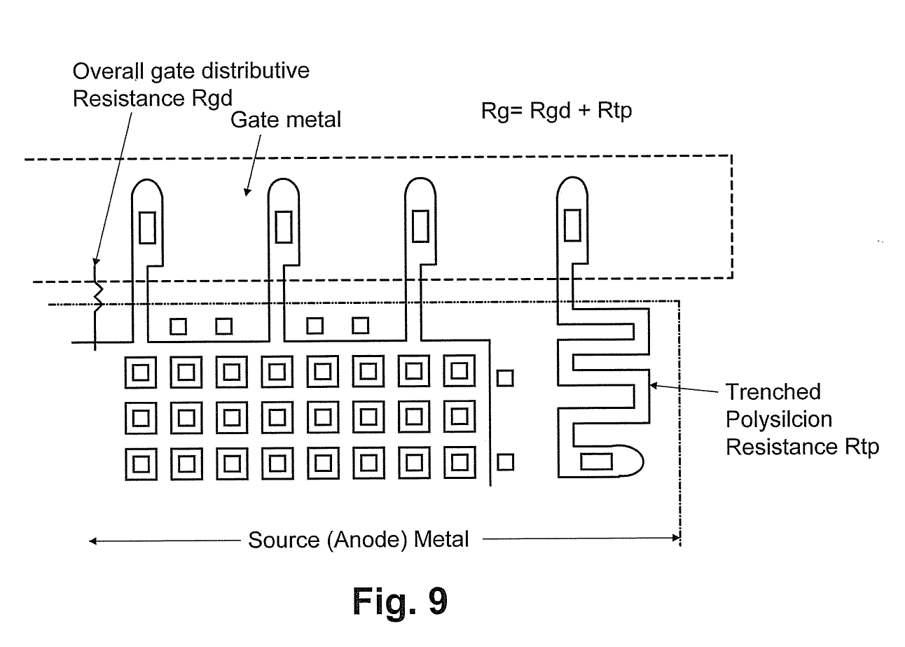

FIG. 9 is top view of another preferred embodiment which has a gate metal contacting the second type trenched gates through gate contacts, and a trenched poly-silicon resistor disposed between the gate metal and the source metal; and an embedded gate resistor Rg including said trenched poly-silicon resistor Rtp and an overall gate distributive resistance Rgd between the first type trenched gates to the gate metal.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A semiconductor device comprising:
a source electrode, a gate electrode and a drain electrode;
said gate electrode connected to said source electrode through an embedded gate resistor built in said semiconductor device; and
said source electrode and drain electrode served as an anode electrode and a cathode electrode of a MOS rectifier, respectively.

2. The semiconductor device of claim 1 further comprising:
a substrate of a first conductivity type and an epitaxial layer of said first conductivity type, wherein said epitaxial layer formed onto top surface of said substrate and having lower doping concentration than said substrate;
a body region of a second conductivity type opposite to said first conductivity type, wherein said body region located near top surface of said epitaxial layer;
a plurality of first type trenched gates as said gate electrode and at least a second type trenched gates penetrating through said body region and extending into said epitaxial layer, said first type trenched gates disposed in an active area and extended to a gate contact area in which said second type trenched gate having a greater width than said first type trenched gates in said active area as wider trenched gates for electrically connecting to an source metal as said source electrode;
a source region of said first conductivity type adjacent said first type trenched gate disposed only in said active area but not in termination area and the regions adjacent to said second type trenched gate in said gate contact area;
said source and body regions shorted with said source metal, and connected to said first type trenched gates through said embedded gate resistor disposed between said first type trenched gates and said source metal; and
a drain metal formed on rear side of said substrate as said drain electrode.

3. The semiconductor device of claim 2, wherein said embedded gate resistor is an overall gate distributive resistance from said first type trenched gates to said second type trenched gates, composed of a doped poly-silicon layer filled in multiple trenches.

4. The semiconductor device of claim 2 further comprising a gate metal contacting said second type trenched gates through gate contacts, and a trenched poly-silicon resistor disposed between said gate metal and said source metal; and said embedded gate resistor including said trenched poly-silicon resistor and an overall gate distributive resistance between said first type trenched gates to said gate metal.

5. The semiconductor device of claim 2, wherein said source metal is connected to said source region, said body region and said second type trenched gate by planar contact.

6. The semiconductor device of claim 5 further comprising an ohmic body contact region of said second conductivity type within said body region and between a pair of said source regions, wherein said ohmic body contact region has a higher doping concentration than said body region to reduce contact resistance.

7. The semiconductor device of claim 2, wherein said source metal is formed onto a contact interlayer and connected to said source region and said body region by trenched source-body contact positioned in a source-body contact trench which being penetrating through said contact interlayer, said source region and extending into said body region.

8. The semiconductor device of claim 7 further comprising an ohmic body contact region of said second conductivity type within said body region and surrounding at least bottom of said source-body contact trench underneath said source region, wherein said ohmic body contact region has a higher doping concentration than said body region to reduce contact resistance.

9. The semiconductor device of claim 2, wherein said source metal is formed over a contact interlayer and connected to said second type trenched gate by a trenched gate contact positioned in a gate contact trench which being penetrating through said contact interlayer and extending into said second type trenched gate.

10. The semiconductor device of claims 7 and 9, wherein said trenched source-body contact and said trenched gate contact is implemented by a metal plug filling into said source-body contact trench and said gate contact trench, respectively, wherein said metal plug is padded by a barrier layer.

11. The semiconductor device of claim 10, wherein said metal plug is tungsten plug and said barrier layer is Ti/TiN or Co/TiN or Ta/TiN.

12. The semiconductor device of claims 7 and 9, wherein said trenched source-body contact and said trenched gate contact is implemented by filling said source metal into said source-body contact trench and said gate contact trench, respectively.

13. The semiconductor device of claim 2 further comprising multiple of third type trenched gates in said termination area, penetrating through said body region and extending into said epitaxial layer with floating voltage to form trenched floating rings.

14. The semiconductor device of claim 2, wherein said termination area comprises a field metal plate and said body region of said second conductivity type underneath, wherein said filed metal plate is implemented by extending said source metal covering said body region and portion of said epitaxial layer.

15. The semiconductor device of claim 2, wherein said termination area further comprises a deep body region of said second conductivity type underneath said source metal and wrapping around said body region in said termination area and said second type trenched gate.

16. The semiconductor device of claim 15, wherein said termination area further comprises multiple deep body regions having floating voltage without having said field metal plate covered above.

17. The semiconductor device of claim 2, wherein said body region is shallower than the first and second type trenched gates for Rds reduction.

18. The semiconductor device of claim 1 wherein said embedded resistor having a resistance from 0.5 ohms to 200 ohms.

19. The semiconductor device of claim 2 further comprising a on-resistance reduction region of said first conductivity type surrounding at least bottoms of said first and said second type trenched gates and connecting to said body region, having doping concentration heavier than said epitaxial layer.

20. The semiconductor device of claim 2 wherein said first and said second trenched gate are composed of a conductive material such as doped poly-silicon with a gate oxide in gate trenches.

21. The semiconductor device of claim 20 wherein said gate oxide is a single gate oxide.

22. The semiconductor device of claim 20 wherein said gate oxide is a double gate oxide, each of said trenched gates includes an upper gate portion and a lower gate portion wherein said lower gate portion is surrounded with a lower gate oxide layer having a greater thickness than an upper gate oxide layer surrounding said upper gate portion, and said body region disposed above said lower gate portion of said trenched gate.
